(19) United States
(12) Patent Application Publication
(10) Pub. No.: US 2026/0201143 A1
(43) Pub. Date: Jul. 16, 2026

(54) INSULATING RESIN COMPOSITION, CURED PRODUCT AND ELECTRONIC COMPONENT

(71) Applicant: NAMICS CORPORATION, Niigata-shi, Niigata (JP)

(72) Inventors: Hirotatsu IKARASHI, Niigata-shi, Niigata (JP); Toshiyuki SATO, Niigata-shi, Niigata (JP)

(73) Assignee: NAMICS CORPORATION, Niigata-shi, Niigata (JP)

(21) Appl. No.: 19/132,580

(22) PCT Filed: Oct. 25, 2023
(86) PCT No.: PCT/JP2023/038447

§ 371 Date: May 23, 2025

(30) Foreign Application Priority Data
Nov. 24, 2022 (JP) 2022-187282

(51) Int. Cl. C08K 3/36; C08F 2/50; C08F 220/18; C08F 222/10; C08G 59/32; C08G 59/38; C08G 59/50; C08G 59/62; C08K 9/06; C08L 33/06; C08L 35/02; C08L 63/00; H10W 74/47

(52) U.S. Cl. CPC C08K 3/36; C08F 2/50; C08F 220/1811; C08F 222/102; C08G 59/3227; C08G 59/38; C08G 59/5073; C08G 59/621; C08K 9/06; C08L 33/06; C08L 35/02; C08L 63/00; C08K 2201/005; C08K 2201/011; C08L 2203/20; H10W 74/47

(57) ABSTRACT

An insulating resin composition includes: (A) inorganic particles with an average particle size (D50) of 0.02 to 0.5 μm, (B) a polyfunctional thermo-curable compound, and (C) a curing agent, wherein the insulating resin composition has a viscosity of 400 mPa-s or less as measured with an E-type viscometer at 25° C. and 50 rpm.

### FIELD OF THE INVENTION

The present invention relates to insulating resin compositions, cured products thereof, and electronic components containing the cured products.

### BACKGROUND ART

Printed electronics, in which conductive or insulating resin compositions are printed directly onto objects based on digital data to form circuits, batteries, various sensors, or insulation patterns, is one field that has been attracting attention in recent years. One printing technology that has long been used as a representative printing technology for printed electronics is inkjet printing technology. Piezo-type inkjet printing technology ejects droplets of ink from nozzles as small as 20 to 50 μm in diameter by applying pressure to the ink inside the nozzles.

Since the size of droplets ejected from the inkjet head is 10 to 100 μm in diameter, there is a limit to the line width, with the minimum feasible line width being 30 μm or more. In addition, the narrow printing gap between the nozzle surface and the object to be printed makes it suitable for printing on a two-dimensional flat surface, but it poses a challenge when used for printing on a three-dimensional curved surface.

In recent years, aerosol jet printing technology has been attracting attention as a technology to overcome the challenges faced by inkjet printing technology. Aerosol jet printing technology is a technology in which the generated aerosol is sprayed with gas from a fine nozzle (see, for example, Patent Document 1). In aerosol jet printing technology, tiny droplets of 10 μm or less in diameter are created and transported by gas to the atomization section (nozzle), where the on-off of the jet from the nozzle to the substrate is digitally controlled, making it possible to create fine patterns, for example, with a minimum line width of 10 μm. This aerosol jet printing technology also enables printing on substrates with irregularities of several millimeters and on three-dimensional curved surfaces because the distance between the substrate and nozzle during printing is wide, allowing printing with a printing gap of about 5 mm.

Patent Document 2 discloses a resin composition for inkjet application containing a monoacrylate with a viscosity of less than 3 mPa-s at room temperature and a filler with a maximum particle size of less than 3 μm, as an insulating resin composition for inkjet application that can be applied by inkjet method, can maintain its shape after application, and can reduce void generation after curing.

### PRIOR ART REFERENCE

### Patent Document

Patent Document 1: Japanese Unexamined Patent Publication (Translation of PCT Application) No. 2011-502741
Patent Document 2: Japanese Unexamined Patent Publication No. 2018-117002

### SUMMARY OF THE INVENTION

### Problems to be Solved by the Invention

In aerosol jet printing technology, the substance to be ejected must be aerosolized, which requires the ability to form micro-droplets of 10 μm or less in diameter. However, when conventional curable resin compositions such as the insulating resin composition for inkjet printing described in Patent Document 2, for example, were attempted to be applied to aerosol jet printing technology, it was found that they were not suitable for aerosol jet printing technology because micro-droplets could not be formed or their ejection was poor.

It is an object of the present invention to provide an insulating resin composition suitable for aerosol jet printing technology.

Specific measures to solve the aforementioned problems are as follows.

The first aspect of the invention includes the following insulating resin compositions.

[1] An insulating resin composition comprising
(A) inorganic particles with an average particle size (D50) of 0.02 to 0.5 μm,
(B) a polyfunctional thermo-curable compound, and
(C) a curing agent,
   the insulating resin composition having a viscosity of 400 mPa-s or less as measured with an E-type viscometer at 25° C. and 50 rpm.

[2] The insulating resin composition as described in [1] above, wherein the (A) inorganic particles are surface-treated with a (meth)acrylic-based surface-treating agent.

[3] The insulating resin composition as described in [1] or [2] above, wherein the (B) polyfunctional thermo-curable compound contains a bifunctional thermo-curable compound.

[4] The insulating resin composition as described in any one of [1] to [3] above, further comprising (D) a monofunctional reactive diluent.

[5] The insulating resin composition as described in [4] above, wherein a content of the (D) monofunctional reactive diluent is 40 to 80 parts by mass relative to 100 parts by mass of the total of the (B) polyfunctional thermo-curable compound, the (C) curing agent and the (D) monofunctional reactive diluent.

[6] The insulating resin composition as described in any one of [1] to [5] above, wherein a content of the (A) inorganic particles is 15 to 50 parts by mass relative to 100 parts by mass of the resin composition.

[7] The insulating resin composition as described in any one of [1] to [6] above, substantially free of particles with a particle size larger than 1.0 sm.

[8] The insulating resin composition as described in any one of [1] to [7] above, for use in aerosol jet printing.

[9] The insulating resin composition as described in any one of [1] to [7] above, for use in for inkjet printing.

The second aspect of the invention includes the following cured product.

[10]A cured product in which the insulating resin composition as described in any one of [1] to [9] above has been cured.

The third aspect of the invention includes the following electronic component.

[11] An electronic component comprising the cured product as described in [10] above.

Aspects of the present invention also include printing methods and use of the following embodiments.

[12] An aerosol jet printing method comprising a step of aerosol jet printing the insulating resin composition as described in any one of [1] to [9] above onto an object to be printed.

[13] An inkjet printing method comprising a step of inkjet printing the insulating resin composition described in any one of [1] to [9] above onto an object to be printed.

[14] Use of the insulating resin composition described in any one of [1] to [9] above in aerosol jet printing.

[15] Use of the insulating resin composition described in any one of [1] to [9] above in inkjet jet printing.

### Effects of the Invention

According to the first aspect of the present invention, an insulating resin composition suitable for aerosol jet printing technology can be obtained. The insulating resin composition of this first aspect is also suitable for inkjet printing technology. According to the second aspect of the present invention, a cured product of the insulating resin composition applied by aerosol jet printing or inkjet printing can be obtained. Furthermore, according to the third aspect of the present invention, electronic components containing such cured products can be obtained.

### MODE FOR CARRYING OUT THE INVENTION

In accordance with common practice in the field of synthetic resins, this specification may use names containing the term “resin”, which usually refers to polymers (especially synthetic polymers), for components of curable resin compositions prior to curing, even though the components are not polymers.

### [Insulating Resin Composition]

The insulating resin composition which is the first aspect of the invention contains:
(A) inorganic particles with an average particle size (D50) of 0.02 to 0.5 μm,
(B) a polyfunctional thermo-curable compound, and
(C) a curing agent,
   wherein the insulating resin composition has a viscosity of 400 mPa-s or less as measured with an E-type viscometer at 25° C. and 50 rpm.
   According to this aspect, an insulating resin composition suitable for aerosol jet printing technology can be obtained.
   (A) Inorganic Particles with an Average Particle Size (D50) of 0.02 to 0.5 μm

The insulating resin composition of the present aspect contains (A) inorganic particles with an average particle size (D50) of 0.02 to 0.5 μm (hereinafter also referred to as “(A) inorganic particles” or “Component (A)”). Component (A) acts as a filler and maintains an appropriate modulus of elasticity of the cured product made by curing the resin composition, and can also lower the linear expansion coefficient of the cured product. Examples of inorganic particles include, but are not limited to, silica, alumina, magnesium oxide, and other insulating inorganic particles. In this aspect, the inorganic particles are preferably silica particles.

In this specification, the average particle size (D50) is the particle size corresponding to the cumulative frequency of 50% of the total inorganic particles, and can be obtained from the particle size distribution measurement using the Microtrac method (laser diffraction scattering method).

In this aspect, it is more preferred that the (A) inorganic particles are surface-treated with a (meth)acrylic-based surface-treating agent. In aerosol jet printing technology, it is a mechanism that generates micro-droplets (aerosols) of 1 to 5 μm in diameter and transfers them through a gas to the nozzle, so the particle size of the inorganic particles must be smaller than the micro-droplets. However, as the particle size of inorganic particles is reduced, the viscosity of the resin composition increases, resulting in an inability to aerosolize or eject from a nozzle. By including inorganic particles that have been surface-treated with a (meth)acrylic-based surface-treating agent, the viscosity of the resin composition, measured with an E-type viscometer at 25° C. and 50 rpm, can be lowered to 400 mPa-s or less, even if the particle size of the inorganic particles is small.

The surface-treating agent has two or more different functional groups in the molecule, one of which is a functional group that chemically bonds to the inorganic material and the other is a functional group that chemically bonds to the organic material. Examples of surface-treating agents include, but are not limited to, silane surface-treating agents, aluminum surface-treating agents, and titanium surface-treating agents, depending on the type of functional group that chemically bonds to the inorganic material. When the inorganic particles are silica particles, it is preferable to use a silane surface-treating agent.

(Meth)acrylic-based surface-treating agents have acryloyl or methacryloyl groups as functional groups that chemically bond to organic materials.

Specific examples of (meth)acryl-silane-based surface-treating agents include, but are not limited to, 3-methacryloxypropyltrimethoxysilane (e.g., commercially available KBM503 from Shin-Etsu Chemical Co., Ltd.), 3-methacryloxypropyl methyl dimethoxysilane (e.g., commercially available KBM502 from Shin-Etsu Chemical Co., Ltd.), 3-methacryloxypropyl methyl diethoxysilane (e.g., commercially available KBE502 from Shin-Etsu Chemical Co., Ltd.), 3-methacryloxypropyltriethoxysilane (e.g., commercially available KBE503 from Shin-Etsu Chemical Co., Ltd.), and the like.

Specific examples of acrylic-silane-based surface-treating agents include, but are not limited to, 3-acryloxypropyltrimethoxysilane (e.g., commercially available KBM-5103 from Shin-Etsu Chemical Co., Ltd.), and the like.

Any one type of (meth)acrylic-based surface-treating agents may be used alone, or two or more may be used in combination.

The average particle size (D50) of the (A) inorganic particles is 0.02 to 0.5 μm, preferably 0.03 to 0.4 μm, and more preferably 0.04 to 0.3 μm from the viewpoint of wettability to resin and dispersibility in resin.

In this aspect, the content of (A) inorganic particles is preferably 10 to 60 parts by mass and more preferably 15 to 50 parts by mass relative to 100 parts by mass of the resin composition from the viewpoint of adjusting the viscosity of the resin composition and controlling cure shrinkage of the cured product.

The insulating resin composition of this aspect is preferably substantially free of particles with a particle size larger than 1.0 μM. As used herein, particles with a particle size larger than 1.0 μm are inorganic particles such as silica particles, for example, or organic particles made of resins such as fluoropolymers or acrylic resins, for example, that have a particle size larger than 1.0 μm. This prevents nozzle clogging when the resin composition is applied by the aerosol jet printing method.

### (B) Polyfunctional Thermo-Curable Compound

The resin composition of the present aspect contains (B) a polyfunctional thermo-curable compound (hereinafter also referred to as “Component (B)”). (B) Polyfunctional thermo-curable compounds include thermal and light curable compounds. (B) Polyfunctional thermo-curable compound has two or more functional groups, which can cure the resin composition by forming a cross-linking network between Component (B) and the (C) curing agent described below through heat treatment or by causing a radical polymerization reaction of Component (B) through heat treatment and/or UV treatment, to provide adhesive strength. Examples of polyfunctional thermo-curable compounds include, but are not limited to, polyfunctional (meth)acrylate compounds having two or more (meth)acryloyloxy groups, polyfunctional epoxy compounds having two or more epoxy groups, polyfunctional maleimide compounds having two or more maleimide groups, polyfunctional allyl ester compounds with two or more allyl ester groups, and the like. In some embodiments, the (B) polyfunctional thermo-curable compound is preferably a polyfunctional (meth)acrylate compound, a polyfunctional epoxy compound, or a combination thereof.

Polyfunctional (meth)acrylate compounds can be cured by heat and/or UV treatment. Examples of polyfunctional (meth)acrylate compounds include, but are not limited to, trimethylolpropane tri(meth)acrylate, 3-methyl-1.5 pentanediol di(meth)acrylate, glycidyl (meth)acrylate, ethylene glycol di(meth)acrylate, propylene glycol di(meth)acrylate, 1,4-butanediol di(meth)acrylate, 1,6-hexanediol di(meth)acrylate, 1,9-nonanediol di(meth)acrylate, 1,3-butanediol di(meth)acrylate, 1,10-decanediol di(meth)acrylate, tetramethylene glycol di(meth)acrylate, glycerin di(meth)acrylate, trimethylolpropane di(meth)acrylate, pentaerythritol di(meth)acrylate, pentaerythritol tri(meth)acrylate, and the like.

Polyfunctional epoxy compounds can be cured by heat treatment. Examples of polyfunctional epoxy compounds include, but are not limited to, bisphenol A epoxy compounds, bisphenol F epoxy compounds, phenol novolac epoxy compounds, alicyclic epoxy compounds, tetrakis(hydroxyphenyl)ethane type or tris(hydroxyphenyl)methane type epoxy compounds, which are polyfunctional and have many benzene rings, biphenyl epoxy compounds, triphenolmethane epoxy compounds, polybutadiene epoxy compounds (epoxidized polybutadiene), naphthalene epoxy compounds, dicyclopentadiene epoxy compounds, aminophenol epoxy compounds, silicone epoxy compounds, and the like. Polyglycidyl esters such as diglycidyl ether of bisphenol A ethylene oxide adduct and diglycidyl ether of bisphenol A propylene oxide adduct, reaction products of p-xylylene glycol and 1-chloro-2,3-epoxypropane, and the like can also be used as polyfunctional epoxy compounds.

Polyfunctional maleimide compounds can be cured by heat and/or UV treatment. Examples of polyfunctional maleimide compounds include, but are not limited to, bismaleimide compounds such as N,N′-(4,4′-diphenylmethane) bismaleimide, bis(3-ethyl-5-methyl-4-maleimidophenyl) methane, and 2,2-bis[4-(4-maleimidophenoxy)phenyl]propane. Other examples of polyfunctional maleimide compounds include compounds obtained by the reaction of diamine dimerate with maleic anhydride and compounds obtained by the reaction of maleimidated amino acids such as maleimidoacetic acid and maleimidocaproic acid with polyols. Maleimidated amino acids are obtained by reacting maleic anhydride with aminoacetic acid or aminocaproic acid. For polyols, polyether polyol, polyester polyol, polycarbonate polyol, and poly(meth)acrylate polyol are preferred, and those without aromatic rings are especially preferred. Since maleimide groups can react with allyl groups, use of polyfunctional maleimide compounds and polyfunctional allyl ester compounds in combination is also preferred. Aliphatic compounds are preferred as polyfunctional allyl ester compounds, especially those obtained by ester exchange of cyclohexanediallyl esters with aliphatic polyols.

In this aspect, from the viewpoint of viscosity of the resin composition, it is preferred that the (B) polyfunctional thermo-curable compound includes bifunctional thermo-curable compounds. In some embodiments, from the viewpoint of increasing the modulus of elasticity of the cured product, it is preferred that the (B) polyfunctional thermo-curable compound includes a trifunctional or more thermo-curable compound. In some embodiments, it is preferred that the (B) polyfunctional thermo-curable compound includes a combination of a bifunctional thermo-curable compound and a trifunctional or higher thermo-curable compound.

It is preferred that the (B) polyfunctional thermo-curable compound be liquid at 25° C.

In this aspect, the content of the (B) polyfunctional thermo-curable compound is preferably 20 to 80 parts by mass, more preferably 20 to 75 parts by mass, and even more preferably 30 to 70 parts by mass relative to 100 parts by mass of the resin composition from the viewpoint of moderately increasing the modulus of elasticity of the cured product.

### (C) Curing Agent

The resin composition of the present aspect contains (C) a curing agent (hereinafter also referred to as “Component (C)”). This allows the resin composition to be cured by forming a cross-linking network between Component (B) and Component (C) by heat treatment, or by a radical polymerization reaction of Component (B) initiated by Component (C) by heat treatment and/or UV treatment. In this aspect, the (C) curing agent includes (C1) a curing agent for cross-linking reaction and (C2) a curing agent for radical polymerization reaction. As the (C1) curing agent for crosslinking reaction, phenolic curing agents, acid anhydride curing agents, amine curing agents, modified imidazole curing agents, hydrazide compounds, dicyandiamide, thiol curing agents, and the like can be used, but are not limited to these. Phenolic curing agents are more preferred from the viewpoint of adhesion of resin compositions. In this aspect, the (C1) curing agent for cross-linking reaction also includes so-called curing accelerators that catalytically act and promote cross-linking. The (C2) curing agent for radical polymerization reaction includes photo-radical polymerization initiators and thermal radical polymerization initiators. The (C) curing agent can be selected according to the type of Component (B).

### (C1) Curing Agent for Cross-Linking Reaction

When Component (B) contains a polyfunctional thermo-curable compound such as a polyfunctional epoxy compound, the resin composition of this aspect preferably contains (C1) a curing agent for crosslinking reaction.

Phenolic resins, which are known as curing agents for epoxy resins, can be used as phenolic curing agents. Specific examples of phenolic curing agents include, but are not limited to, resol or novolac phenolic resins, alkyl resol phenolic resins, alkyl novolac phenolic resins, aralkyl novolac phenolic resins, xylene resins, allyl phenolic resins, and the like. The hydroxyl (011) group equivalent of the phenolic curing agent is preferably 80 to 250 g/eq, and more preferably 80 to 200 g/eq. In the case of alkyl resol or alkyl novolac phenolic resins, alkyl groups with 1 to 18 carbons can be used, and those with 2 to 10 carbons such as ethyl, propyl, butyl, pentyl, hexyl, octyl, nonyl and decyl are preferred. Examples of commercially available phenolic curing agents include, but are not limited to, phenolic resin curing agents (trade name: MEH8005) available from Meiwa Kasei Ltd.

As acid anhydride curing agents, acid anhydrides known as curing agents for epoxy resins can be used. Specific examples of acid anhydride curing agents include, but are not limited to, phthalic anhydride, maleic anhydride, dodecenyl succinic anhydride, trimellitic anhydride, benzophenone tetracarboxylic anhydride, tetrahydro phthalic anhydride, hexahydro phthalic anhydride, and the like. Examples of commercial products of acid anhydride curing agents include, but are not limited to, an acid anhydride curing agent (trade name: YH307) available from Mitsubishi Chemical Corporation.

Amine curing agents include aliphatic and aromatic amines as well as imidazoles. Among these, imidazoles are also used as curing accelerators that promote the reaction between epoxy compounds and curing agents.

Examples of aliphatic amines include, but are not limited to, aliphatic polyamines such as diethylenetriamine, triethylenetetraamine, tetraethylenepentamine, trimethylhexamethylenediamine, m-xylenediamine and 2-methylpentamethylenediamine; alicyclic polyamines such as isophoronediamine, 1,3-bisaminomethylcyclohexane, bis(4-aminocyclohexyl)methane, norbornenediamine and 1,2-diaminocyclohexane; piperazine-type polyamines such as N-aminoethylpiperazine and 1,4-bis(2-amino-2-methylpropyl)piperazine; and the like.

Examples of aromatic amines include, but are not limited to, diaminodiphenylmethane, m-phenylenediamine, diaminodiphenylsulfone, diethyltoluenediamine, trimethylene bis(4-aminobenzoate), polytetramethylene oxide-di-p-aminobenzoate, tris(dimethylaminomethyl)phenol, benzyl dimethylamine, 1,8-diazabicyclo(5.4.0)-7-undensen, and the like.

Examples of imidazoles include, but are not limited to, imidazole compounds such as 2-ethyl-4-methylimidazole, 2-phenylimidazole, 2-methylimidazole, 2-phenyl-4-methylimidazole, 1-cyanoethyl-2-methylimidazole, 1-cyanoethyl-2-undecylimidazole, 2-phenyl-4-methyl-5-hydroxymethylimidazole and 2-phenyl-4,5-dihydroxymethylimidazole.

Examples of modified imidazole curing agents include epoxy-imidazole adduct compounds and acrylate-imidazole adduct compounds. Examples of commercially available epoxy-imidazole adduct compounds include, but are not limited to, curing agents available from Ajinomoto Fine-Techno Co., Inc. (trade names: Ajicure PN-23, Ajicure PN-40), curing agent available from Asahi Kasei Corporation (trade name: Novacure HX-3721), curing agent available from T&K TOKA CO., LTD. (trade name: Fujicure FX-1000), and the like. Examples of commercially available products of acrylate-imidazole adduct compounds include, but are not limited to, curing agents available from ADEKA Corporation (trade name: EH2021).

Examples of thiol curing agents include, but are not limited to, 2-ethylhexyl-3-mercaptopropionate, n-octyl-3-mercaptopropionate, tetraethylene glycol bis(3-mercaptopropionate), trimethylolpropane tris(3-mercaptopropionate), tris-[(3-mercaptopropionyloxy)-ethyl]-isocyanurate, polysulfide polymer, 1,4-bis(3-mercaptobutyryloxy)butane, 1,3,5-tris(3-mercaptobutyryloxyethyl)-1,3,5-triazine-2,4,6(1H,3H,5H)-trion, trimethylolpropane tris(3-mercaptobutyrate), trimethylolethane tris(3-mercaptobutyrate), and the like. Thiol curing agents can also react with polyfunctional (meth)acrylate compounds and polyfunctional maleimide compounds.

Any one type of (C1) curing agents may be used alone, or two or more may be used in combination.

The content of (C1) curing agent is preferably 0.1 to 10 parts by mass relative to 100 parts by mass of the resin composition (excluding solvent) from the viewpoint of storage stability and curability.

### (C2) Curing Agent for Radical Polymerization Reaction

When Component (B) contains a polyfunctional thermo-curable compound such as a polyfunctional (meth)acrylate compound or a polyfunctional maleimide compound, the resin composition of this aspect preferably contains (C2) a curing agent for radical polymerization reaction.

When Component (B) contains a polyfunctional (meth)acrylate compound or a polyfunctional maleimide compound, the resin composition of this aspect may contain a photo-radical polymerization initiator. The inclusion of a photo-radical polymerization initiator promotes UV curing. This allows, for example, UV curing to temporarily fix the resin composition. Examples of photo-radical polymerization initiators include alkylphenone compounds and acylphosphine oxide compounds.

Examples of alkylphenone compounds include, but are not limited to, benzyl dimethyl ketals such as 2,2-dimethoxy-1,2-diphenylethan-1-one (e.g., commercially available as Omnirad 651 from IGM Resins B.V.); α-aminoalkylphenones, such as 2-methyl-2-morpholino(4-thiomethylphenyl)propan-1-one (e.g., commercially available as Omnirad 907 from IGM Resins B.V.); α-hydroxyalkylphenones such as 1-hydroxy-cyclohexyl-phenyl-ketone (e.g., commercially available as Omnirad 184 from IGM Resins B.V.); 2-dimethylamino-2-(4-methyl-benzyl)-1-(4-morpholin-4-yl-phenyl)-butan-1-one (e.g., commercially available as Omnirad 379EG from IGM Resins B.V.), 2-benzyl-2-(dimethylamino)-4′-morpholinobutyrophenone (e.g., commercially available as Omnirad 369 from IGM Resins B.V.), and the like.

Examples of acylphosphine oxide compounds include, but are not limited to, 2,4,6-trimethylbenzoyl-diphenyl-phosphine oxide (e.g., commercially available as Omnirad TPO H from IGM Resins B.V.), bis(2,4,6-trimethylbenzoyl)-phenylphosphine oxide (e.g., commercially available as Omnirad 819 from IGM Resins B.V.), and the like.

Any one type of photo-radical polymerization initiators may be used alone, or two or more may be used in combination.

When the resin composition contains a photo-radical polymerization initiator, the content of the photo-radical polymerization initiator is preferably 0.01 to 5% by mass and more preferably 0.1 to 3% by mass relative to the total mass of the resin composition from the viewpoint of curing speed and pot life of the resin composition.

When Component (B) contains a polyfunctional (meth)acrylate compound or a polyfunctional maleimide compound, the resin composition of this aspect may contain a thermal radical polymerization initiator. By including a thermal radical polymerization initiator in the resin composition, it is possible to cure the resin composition in a short heating time. The thermal radical polymerization initiators that can be used are not particularly limited and known materials can be used. Specific examples of thermal radical polymerization initiators include, but are not limited to, dialkyl peroxides such as dicumyl peroxide, t-butylcumyl peroxide, 1,3-bis(2-t-butylperoxyisopropyl)benzene or 2,5-dimethyl-2,5-bis(t-butylperoxy)hexane; 1,1-bis(t-butylperoxy)cyclohexane, 1,1-bis(t-butylperoxy)-3,3,5 trimethylcyclohexane, 1,1-bis(t-amylperoxy)cyclohexane, 2,2-bis(t-butylperoxy)butane; peroxyketals such as n-butyl 4,4-bis(t-butylperoxy)valerate or ethyl 3,3-(t-butylperoxy)butyrate; and alkyl peroxyesters such as t-butylperoxy 2-ethylhexanoate, 1,1,3,3-tetramethylbutylperoxy-2-ethylhexanoate, t-butylperoxyisobutyrate, t-butylperoxymaleate, or t-butylperoxybenzoate. Any one type of thermal radical polymerization initiators may be used alone, or two or more may be used in combination.

When the resin composition contains a thermal radical polymerization initiator, the content of the thermal radical polymerization initiator is preferably 0.01 to 5% by mass, more preferably 0.1 to 3% by mass relative to the total mass of the resin composition.

Any one of the (C) curing agents may be used alone, or two or more may be used in combination.

### (D) Monofunctional Reactive Diluent

The resin composition of this aspect preferably contains (D) a monofunctional reactive diluent (hereinafter also referred to as “Component (D)”). The viscosity of the resin composition can be lowered by including (D) a monofunctional reactive diluent. In addition, because it is monofunctional, it does not form cross-links, and the increase in internal stress of the cured product due to too high cross-link density can be suppressed, and the cure shrinkage of the cured product can be suppressed and flexibility can be provided. Examples of the (D) monofunctional reactive diluent include monofunctional (meth)acrylate compounds, monofunctional maleimide compounds, and monofunctional epoxy compounds. In this aspect, the (D) monofunctional reactive diluent is preferably a monofunctional (meth)acrylate compound. In some embodiments, it is preferred that the (D) monofunctional reactive diluent includes a monofunctional reactive diluent with a rigid structure such as isobornyl structure or dicyclopentadienyl structure. By including a monofunctional reactive diluent with a rigid structure, the resin composition can have a low viscosity, can provide a high glass transition temperature (Tg) of the cured product, and can provide a low shrinkage rate of the cured product.

Examples of monofunctional (meth)acrylate compounds include, but are not limited to, ethyl (meth)acrylate, trifluoroethyl (meth)acrylate, diethylaminoethyl (meth)acrylate, dimethylaminoethyl (meth)acrylate, glycidyl (meth)acrylate, n-butyl (meth)acrylate, isobutyl (meth)acrylate, tert-butyl (meth)acrylate, isoamyl (meth)acrylate, cyclohexyl (meth)acrylate, 2-ethylhexyl (meth)acrylate, isodecyl (meth)acrylate, isobornyl (meth)acrylate, stearyl (meth)acrylate, lauryl (meth)acrylate, phenoxyethyl (meth)acrylate, benzyl (meth)acrylate, tetrahydrofurfuryl (meth)acrylate, ethoxydiethylene glycol (meth)acrylate, phenoxydiethylene glycol (meth)acrylate, phenoxypolyethylene glycol (meth)acrylate, butoxydiethylene glycol (meth)acrylate, methoxydipropylene glycol (meth)acrylate, methoxypolyethylene glycol (meth)acrylate, methoxytriethylene glycol (meth)acrylate, methoxy polyethylene glycol (meth)acrylate, 2-ethylhexyl diethylene glycol (meth)acrylate, 4-tert-butylcyclohexyl(meth)acrylate, 3-phenoxybenzyl(meth)acrylate, 2-hydroxyethyl(meth)acrylate, 2-hydroxypropyl(meth)acrylate, 2-hydroxybutyl(meth)acrylate, 2-hydroxy-3-phenoxypropyl(meth)acrylate, octyl acrylate, nonyl acrylate, isononyl acrylate, 3,3,5-trimethylcyclohexyl acrylate, cyclic trimethylolpropane formal acrylate, 1-naphthalene methyl (meth)acrylate, 1-ethylcyclohexyl (meth)acrylate, 1-methylcyclohexyl (meth)acrylate, 1-ethylcyclopentyl (meth)acrylate, 1-methylcyclopentyl(meth)acrylate, dicyclopentenyl(meth)acrylate, dicyclopentenyloxyethyl(meth)acrylate, dicyclopentanyl(meth)acrylate, nonylphenoxy polyethylene glycol(meth)acrylate, tetrahydrodicyclopentadienyl(meth)acrylate, 2-(o-phenylphenoxy)ethyl(meth)acrylate, isobornylcyclohexyl(meth)acrylate, (2-methyl-2-ethyl-1,3-dioxolan-4-yl)methyl(meth)acrylate, 1-adamantyl(meth)acrylate, 3-hydroxy-1-adamantyl(meth)acrylate, 2-methyl-2-adamantanyl(meth)acrylate, 2-ethyl-2-adamantanyl(meth)acrylate, 2-isopropyladamantan-2-yl(meth)acrylate, 3-hydroxy-1-adamantyl(meth)acrylate, (adamantane-1-yloxy)methyl(meth)acrylate, 2-isopropyl-2-adamantyl(meth)acrylate, 1-methyl-1-ethyl-1-adamantylmethanol(meth)acrylate, 1,1-diethyl-1-adamantylmethanol(meth)acrylate, 2-cyclohexylpropan-2-yl(meth)acrylate, 1-isopropylcyclohexyl(meth)acrylate, 1-methylcyclohexyl(meth)acrylate, 1-ethylcyclopentyl(meth)acrylate, 1-methylcyclohexyl(meth)acrylate, tetrahydropyranyl(meth)acrylate, tetrahydro-2-furanyl(meth)acrylate, 2-oxotetrahydrofuran-3-yl(meth)acrylate, (5-oxotetrahydrofuran-2-yl)methyl(meth)acrylate, (2-oxo-1,3-dioxolan-4-yl)methyl(meth)acrylate, 1-ethoxyethyl(meth)acrylate, and the like. Any one of them may be used alone, or two or more may be used in combination. Among these, monofunctional reactive diluents with an isobornyl structure, such as isobornyl (meth)acrylate, and monofunctional reactive diluents with dicyclopentadienyl structure such as dicyclopentenyl(meth)acrylate, dicyclopentanyl(meth)acrylate, dicyclopentenyloxyethyl(meth)acrylate are preferred. Any one of them may be used alone, or two or more may be used in combination.

Examples of monofunctional maleimide compounds include, but are not limited to, maleimide; maleimides containing aliphatic hydrocarbon groups such as methylmaleimide, ethylmaleimide, propylmaleimide, butylmaleimide, hexylmaleimide, octylmaleimide, dodecylmaleimide, stearylmaleimide and cyclohexylmaleimide; maleimides containing aromatic rings such as phenylmaleimide; and the like. Any one of them may be used alone, or two or more may be used in combination.

Examples of monofunctional epoxy compounds include, but are not limited to, aromatic monofunctional epoxy compounds such as phenyl glycidyl ether, cresyl glycidyl ether, p-s-butyl phenyl glycidyl ether, styrene oxide, p-tert-butylphenyl glycidyl ether, o-phenylphenol glycidyl ether, p-phenylphenol glycidyl ether and N-glycidyl phthalimide; aliphatic monofunctional epoxy compounds such as n-butyl glycidyl ether, 2-ethylhexyl glycidyl ether, a,-pinene oxide, allyl glycidyl ether, 1-vinyl-3,4-epoxy cyclohexane, 1,2-epoxy-4-(2-methyloxiranyl)-1-methylcyclohexane, 1,3-bis(3-glycidoxypropyl)-1,1,3,3-tetramethyldisiloxane and neodecanoic acid glycidyl ester. Any one of them may be used alone, or two or more may be used in combination.

Any one of the (D) monofunctional reactive diluents may be used alone, or two or more may be used in combination.

When the resin composition of this aspect contains (D) a monofunctional reactive diluent, the content of the (D) monofunctional reactive diluent is preferably 40 to 80 parts by mass, and more preferably 45 to 70 parts by mass, relative to 100 parts by mass of the total of (B) polyfunctional thermo-curable compound, (C) curing agent and (D) monofunctional reactive diluent. By setting the ratio of (D) monofunctional reactive diluent in the above range, the viscosity of the resin composition can be lowered and the applicability in the aerosol jet method can be further improved.

### (E) Other Additives

The resin composition of this aspect may, if desired, contain other additives, such as carbon black, titanium black, a silane coupling agent, an ion trapping agent, a leveling agent, an antioxidant, a defoaming agent, a viscosity modifier, a flame retardant, or a solvent as needed and to the extent that the properties of the resin composition of this aspect are not impaired. The type and amount of each additive are as usual.

The method of producing the resin composition of this aspect is not limited. For example, Components (A) to (C), and if necessary, Component (D), (E) other additives, and the like can be introduced simultaneously or separately into an appropriate mixing machine and subjected to stirring and mixing while melting by heating, if necessary, to obtain a uniform composition as the resin composition. The equipment for mixing these materials is not limited. A ricer, Henschel mixer, 3-roll mill, ball mill, planetary mixer, bead mill, and the like, equipped with an agitator and heating device can be used. A combination of these devices may also be used as appropriate.

The resin composition thus obtained is thermo-curable and can be cured, for example, by heat treatment at 130 to 200° C. for 30 to 180 minutes.

When Component (B) contains a polyfunctional (meth)acrylate compound or a polyfunctional maleimide compound, the resin composition is light-curable and thermo-curable. In this case, the resin composition can be temporarily fixed by exposing it to light of a predetermined wavelength after application, followed by main curing by applying heat to make a cured product. Specific methods of temporary fixation and main curing are not particularly limited. When the resin composition is light-cured, the light irradiated is, for example, ultraviolet (UV) light. In some embodiments, the resin composition may be light-cured only.

In this aspect, the viscosity of the resin composition, measured with an E-type viscometer at 25° C. and 50 rpm, is 400 mPa-s or less, preferably 350 mPa-s or less, and more preferably 300 mPa-s or less. The resin composition of this aspect is suitable for aerosol jet printing due to its low viscosity while containing inorganic particles with small particle size. The lower limit of viscosity of the resin composition, measured with an E-type viscometer at 25° C. and 50 rpm, is, for example, 50 mPa-s or higher, preferably 100 mPa-s or higher, and more preferably 200 mPa-s or higher, from the viewpoint of reducing cure shrinkage. In some embodiments, the viscosity of the resin composition, measured with an E-type viscometer at 25° C. and 50 rpm, is preferably 50 to 400 Pa-s, more preferably 100 to 350 Pa-s, and even more preferably 200 to 300 Pa-s.

The method of application of the resin composition of this aspect is not particularly limited, and can be provided, for example, to a desired portion of a substrate or the like by a known printing, dispensing, or coating method. Printing or dispensing methods include, but are not limited to, aerosol jet printing, inkjet printing (jet dispense printing), screen printing, flat plate printing, carton printing, metal printing, offset printing, gravure printing, flexographic printing, and methods using air dispensers. Coating methods include, but are not limited to, dip coating, spray coating, bar coater coating, gravure coating, reverse gravure coating, and spin coater coating.

The method of application of the resin composition of this aspect is preferably aerosol jet printing or inkjet printing, and more preferably aerosol jet printing. The use of the insulating resin composition of this aspect in aerosol jet printing or inkjet printing is also an aspect of the present invention.

### [Cured Product of the Resin Composition]

The cured product, which is the second aspect of the present invention, is a cured product in which the resin composition of the first aspect described above has been cured.

From the viewpoint of adhesion property, the cured product of this aspect preferably has a modulus of elasticity of 1.0 to 9.0 GPa, more preferably of 3.5 to 8.0 GPa, and even more preferably of 4.0 to 7.0 GPa. The modulus of elasticity of the cured product can be adjusted by adjusting the type and amount of components of the resin composition. For example, if each component contains a rigid structure such as biphenyl, naphthalene, dicyclopentadiene, cresol novolac, isobornyl, or dicyclopentadienyl, the modulus of elasticity tends to be larger. For example, the inclusion of a trifunctional or more polyfunctional thermo-curable compound tends to increase the modulus of elasticity by increasing the crosslink density.

The cured product of this aspect preferably has a glass transition temperature (Tg) of 60° C. or higher, more preferably 70° C. or higher, and even more preferably 80° C. or higher from the viewpoint of solder reflowability. The Tg of the cured product can be adjusted by adjusting the type and amount of components of the resin composition. For example, if each component contains a rigid structure such as biphenyl, naphthalene, dicyclobentadiene, cresol novolac, isobornyl, or dicyclopentadienyl, the Tg tends to be larger. For example, the inclusion of a trifunctional or more polyfunctional thermo-curable compound tends to increase the Tg by increasing the crosslink density. The upper limit of Tg of the cured product is not particularly limited, and it is preferably 260° C. or less.

### [Electronic Component]

An electronic component, which is the third aspect of the present invention, contains the cured product of the second aspect described above. Electronic components include, for example, semiconductor packages manufactured by bonding a semiconductor chip (die), such as an IC or LSI, to a substrate or other support member, bonding the die to the support member, and then scaling the die with a molding agent. Such semiconductor packages can be mounted on printed circuit boards or motherboards.

### [Printing Method, and Production Method of Cured Product]

Another aspect of the present invention is an aerosol jet printing method, which includes a step of aerosol jet printing the insulating resin composition of the first aspect described above onto an object to be printed.

In aerosol jet printing technology, tiny droplets of 10 μm or less in diameter are created and transported by gas to the atomization section (nozzle), where the on-off of the jet from the nozzle to the substrate is digitally controlled, making it possible to create fine patterns, for example, with a minimum line width of 10 μm. This aerosol jet printing technology also enables printing on substrates with irregularities of several millimeters and on three-dimensional curved surfaces because the distance between the substrate and nozzle during printing is wide, allowing printing with a printing gap of about 5 mm.

The object to be printed is, for example, a component that makes up an electronic component, such as, but not limited to, a semiconductor device, a base material, and the like. The material of the component may be engineering plastic (e.g., LCP (liquid crystal polymer), polyamide, polycarbonate, etc.), ceramics, or metal (e.g., copper, nickel).

Yet another aspect of the invention is a method of producing a cured product, comprising
a step of aerosol jet printing the insulating resin composition of the first aspect described above onto an object to be printed, and
a step of curing the aerosol jet printed insulating resin composition.

Another aspect of the present invention is an inkjet printing method, comprising a step of inkjet printing the insulating resin composition of the first aspect described above onto an object to be printed.

The object to be printed is, for example, a component of an electronic component, such as, but not limited to, a semiconductor device, a base material, and the like. The material of the component may be engineering plastic (e.g., LCP (liquid crystal polymer), polyamide, polycarbonate, etc.), ceramics, or metal (e.g., copper, nickel).

Yet another aspect of the invention is a method of producing a cured product, comprising
a step of inkjet printing the insulating resin composition of the first aspect described above onto an object to be printed, and
a step of curing the inkjet printed insulating resin composition.

### EXAMPLES

Hereinbelow, the present invention will be described in more detail with reference to the following Examples and Comparative Examples, which should not be construed as limiting the scope of the present invention. In the following examples, parts and percentages refer to parts by mass and percentages by mass, unless otherwise noted.

### Examples 1 to 12, and Comparative Examples 1 to 4

### [Preparation of Resin Compositions]

Each of resin compositions was prepared by mixing each of the components in the amounts according to the formulations shown in Table 1 using a three-roll mill. In Table 1, the amount of each component is expressed in parts by mass (unit: g). The ingredients used in Examples and Comparative Examples are as follows.

—(A) Inorganic Particles with an Average Particle Size (D50) of 0.02 to 0.5 μm
(A-1): (Meth)acrylic-based surface-treated silica filler 1 (trade name: YC100-SM1, ADMATECHS COMPANY LIMITED, average particle size (D50): 0.1 μm, surface-treating agent: 3-methacryloxypropyltrimethoxysilane)
(A-2): (Meth)acrylic-based surface-treated silica filler 2 (trade name: YA050C-SM1, ADMATECHS COMPANY LIMITED, average particle size (D50): 0.05 μm, surface-treating agent: 3-methacryloxypropyltrimethoxysilane)
   —(A′) Inorganic Particles Other than Component (A)
(A′-1): (Meth)acrylic-based surface-treated silica filler 3 (trade name: SE2200-SME, ADMATECHS COMPANY LIMITED, average particle size (D50): larger than 1 μm, surface-treating agent: 3-glycidoxypropyltrimethoxysilane)
(A′-2): (Meth)acrylic-based surface-treated silica filler 4 (trade name: YA010C-SM1, ADMATECHS COMPANY LIMITED, average particle size (D50): 0.01 μm, surface-treating agent: 3-methacryloxypropyltrimethoxysilane)
(A′-3): Silica filler without surface treatment (trade name: SEAHOSTAR KE-S30HG, Nippon Shokubai Co., Ltd., average particle size (D50): 0.3 μm)
(A′-4): Trimethyl surface-treated silica filler (AEROSIL® RX50, NIPPON AEROSIL CO., LTD., average particle size (D50): 0.02 to 0.10 μm)

### (B) Polyfunctional Thermo-Curable Compound

(B-1): Trifunctional (meth)acrylate compound (chemical name: trimethylolpropane triacrylate, trade name: Light Acrylate TMP-A, Kyoeisha Chemical Co., Ltd., viscosity: 80 to 120 mPa-s, Cas. No.: 15625-89-5)
(B-2): Bifunctional (meth)acrylate compound 1 (chemical name: 3-methyl-1,5 pentanediol diacrylate, trade name: Light Acrylate MPD-A, Kyoeisha Chemical Co., Ltd., viscosity: 8 mPa-s, Cas. No.: 64194-22-5)
(B-3): Bifunctional (meth)acrylate compound 2 (chemical name: 1,9-nonanediol diacrylate, trade name: Light Acrylate 1.9ND-A, Kyoeisha Chemical Co., Ltd., viscosity: 10 mPa-s, Cas. No.: 107481-28-7)
(B4): Trifunctional epoxy compound (chemical name: N,N-diglycidyl-4-(glycidyloxy)aniline, trade name: jER-630, Mitsubishi Chemical Corporation, viscosity: 5000 to 10,000 mPa-s, Cas. No.: 5026-74-4)
(B-5): Bifunctional epoxy compound 1 (polyoxyalkylene bisphenol A diglycidyl ether, trade name: EP4000S, ADEKA CORPORATION, viscosity: 1800 mPa-s, Cas. No.: 36484-54-5)
(B-6): Bifunctional epoxy compound 2 (tetramethylbiphenyl epoxy compound, trade name: YX4000H, Mitsubishi Chemical Corporation, solid (room temperature), Cas. No:85954-11-6)
(B-7): Bifunctional epoxy compound 3 (Polypropylene glycol type epoxy compound, trade name: PG207GS, NIPPON STEEL Chemical & Material Co., Ltd., viscosity: 20 to 70 mPa-s, Cas. No.: 9072-62-2)

### —(C) Curing Agent

(C-1): Phenolic curing agent (trade name: MEH8005, Meiwa Plastic Industries, Ltd. (currently UBE Corporation), viscosity: 4500 to 7500 mPa-s, Cas. No: 27924-97-6 or 9003-35-4)
(C-2): Imidazole-based curing agent (chemical name: 4-methyl-2-phenylimidazole, trade name: 2P 4MZ, SHIKOKU KASEI HOLDINGS CORPORATION, Cas. No: 827-43-0)
(C-3): 1-hydroxy-cyclohexyl-phenyl-ketone (photo-radical polymerization initiator, trade name: Omnirad 184, 1GM Resins B.V., Solid (room temperature), Cas. No.: 947-19-3)
(C4): 2,4,6-trimethylbenzoyl-diphenyl-phosphine oxide (photo-radical polymerization initiator, trade name: Omnirad TPO H, IGM Resins B.V., Solid (room temperature), Cas. No.: 75980-60-8)
(C-5): 1,1,3,3-tetramethylbutylperoxy 2-ethylhexanoate (thermal radical polymerization initiator, trade name: PEROCTA® O, NOF CORPORATION, liquid (room temperature), Cas. No.: 22288-43-3)

### —(D) Monofunctional Reactive Diluent

(D-1): Isobornyl acrylate (trade name: IBXA, Kyoeisha Chemical Co., Ltd., Cas. No: 5888-33-5)
(D-2): Dicyclopentanyl acrylate (trade name: FA513AS, Resonac Corporation, viscosity: 7 to 17 mPa-s, Cas. No.: 79637-74-4)

In the examples and comparative examples, the properties of the resin compositions and the cured products obtained by curing the resin compositions were measured as follows.

### [Viscosity Measurement]

The viscosity of each resin composition was measured at 25° C., 5 rpm and 50 rpm using a cone plate viscometer TV-22 (cone plate: 1° 34′×R24) available from Toki Sangyo Co., Ltd. The viscosity at 50 rpm is listed in Table 1 as “viscosity”. In the table, “N.A.” means that the viscosity was outside the measurement range and could not be measured. The results are shown in Table 1.

### [Aerosol Jet Printing Evaluation Test]

Each resin composition was evaluated using an aerosol jet dispenser (Aerosol Jet: AJHD2 available from OPTOMEC). The evaluation conditions are as follows: Nozzle 300 (μm), sheath gas 80 sccm, atomization gas 900 sccm, distance between nozzle and substrate 5 mm, printing speed 10 mm/sec. Each resin composition was sprayed onto a glass substrate. Those that could be ejected without clogging the nozzle were designated “o” and those that could not be ejected were designated “x”. The results are shown in Table 1.

### [Inkjet Printing Evaluation Test]

Each resin composition was evaluated using a jet dispenser (AeroJet: MJET-A-2 available from Musashi Engineering, Inc.). The evaluation conditions were as follows. Sheet: W type, Rod: M lot, Nozzle: 26G, Stroke: 100 (μm), Pressure: 125 (MPa), On time: 3.5 (msec), Off time: 5 (msec). Each resin composition was sprayed onto a glass substrate. Those that could be ejected without clogging the nozzle were designated “∘” and those that could not be ejected were designated “x”. The results are shown in Table 1.

### [Modulus of Elasticity and Glass Transition Temperature (Tg) Measurements of Cured Product]

Two glass plates coated with a mold release agent and dried were prepared. The resin composition was applied to one glass plate, and a gap was also placed on the glass plate so that the thickness of the resin composition was approximately 100 μm, and then another glass plate was placed thereon to sandwich the resin composition between the two glass plates. One side of the sample was irradiated with 500 mi/cm² UV light (wavelength 365 nm) using an LED-type UV irradiation system (Omnicure: AC475 from Excelitas). The sample was then turned over and the other side of the sample was irradiated with 500 mJ/cm² UV light (wavelength 365 nm). It was then cured in sheet form under heating conditions of 175° C. for 60 minutes. This was processed to a size of 40 mm×5 mm and used as a test specimen for dynamic viscoelasticity measurements (DMA). DMA measurements were performed using a viscoelasticity measuring device (DMS6100 from Seiko Instruments Inc.) under the following conditions: measurement mode: tensile, temperature increase rate: 3° C./min, measurement frequency: 10 Hz, to obtain the modulus of elasticity and Tg at room temperature of the cured product of the resin composition. In the table, “N.A.” means that the measurement was not possible because it was outside the measurement range. The results are shown in Table 1. The range of modulus of elasticity of the cured product is preferably 1.0 to 9.0 GPa, more preferably 3.5 to 8.0 GPa, and even more preferably 4.0 to 7.0 GPa in terms of adhesion. The range of Tg of the cured product is preferably 60° C. or higher, more preferably 70° C. or higher, and even more preferably 80° C. or higher from the viewpoint of solder reflowability. The upper limit of Tg of the cured product is not particularly limited, and is preferably 260° C. or less.

### [Shrinkage Rate Measurement of Cured Product]

The specific gravity of the resin composition was measured at 25° C. in a 10 cc specific gravity bottle made of polytetrafluoroethylene (PTFE) (liquid specific gravity). Two glass plates coated with a mold release agent and dried were prepared. The resin composition was applied to one glass plate, and a gap was also placed on the glass plate so that the thickness of the resin composition was approximately 300 μm, and then another glass plate was placed thereon to sandwich the resin composition between the two glass plates. One side of the sample was irradiated with 500 mi/cm² UV light (wavelength 365 nm) using an LED-type UV irradiation system (Omnicure: AC475 from Excelitas). The sample was then turned over and the other side of the sample was irradiated with 500 mJ/cm² UV light (wavelength 365 nm). It was then cured in sheet form under heating conditions of 175° C. for 60 minutes. After measuring the weight of the cured film (a, unit: g), the cured film was placed in pure water and defoamed well. The weight of the defoamed cured film (b, unit: g) was measured and the specific gravity was obtained by the following Equation (1) (specific gravity of cured product). Shrinkage rate of the cured product was calculated using the following Equation (3). The results are shown in Table 1.

$$Specific gravity of cured product ( g / {cm}^{3} ) = Weight of cured film ( a ) / Volume ( {cm}^{3} ) \qquad ( 1 )$$

$$Volume ( {cm}^{3} ) = ( ( a ) - ( b ) ) / density of water at temperature c ( g / {cm}^{3} ) \qquad ( 2 )$$

$$Shrinkage rate ( \% ) = \{ 1 - ( specific gravity of liquid / specific gravity of cured product ) \} \times 100 \qquad ( 3 )$$

From the viewpoint of suppressing delamination and cracking, the range of a shrinkage rate of the cured product is preferably 8.0% or less, more preferably 7.0% or less, even more preferably 6.0% or less, and especially preferably 5.0% or less.

TABLE 1

| | | Com. | Com. | Com. | Com. | | | | | |
|---|---|---|---|---|---|---|---|---|---|---|
| | | Ex. 1 | Ex. 2 | Ex. 3 | Ex. 4 | Ex. 1 | Ex. 2 | Ex. 3 | Ex. 4 | Ex. 5 |
| (A) Inorganic | (A-1) | | | | | | | | | |
| particles | (A-2) | | | | | 30 | 30 | 10 | 20 | 30 |
| (A′) Inorganic | (A′-1) | 30 | | | | | | | | |
| particles | (A′-2) | | 30 | | | | | | | |
| (For Comparison | (A′-3) | | | 30 | | | | | | |
| Example) | (A′-4) | | | | 30 | | | | | |
| (D) | (D-1) | 35.01 | 35.01 | 35.01 | 35.01 | | | 45.0 | 40.1 | 35.01 |
| Monofunctional | (D-2) | | | | | | | | | |
| reactive diluent | | | | | | | | | | |
| Component (B): | (B-1) | 8.36 | 8.36 | 8.36 | 8.36 | 8.36 | 8.36 | 11 | 9.6 | 8.36 |
| Polyfunctional | (B-2) | | | | | 28 | 21 | | | |
| (meth)acrylate | (B-3) | | | | | 7 | 14 | | | |
| compound | | | | | | | | | | |
| Component (B): | (B-4) | 4.50 | 4.50 | 4.50 | 4.50 | 4.50 | 4.50 | 6.10 | 5.10 | 4.50 |
| Polyfunctional | (B-5) | 6.32 | 6.32 | 6.32 | 6.32 | 6.32 | 6.32 | 8.1 | 7.2 | 6.32 |
| epoxy compound | (B-6) | 8.69 | 8.69 | 8.69 | 8.69 | 8.69 | 8.69 | 11.2 | 10.0 | 8.69 |
| | (B-7) | 1.9 | 1.9 | 1.9 | 1.9 | 1.9 | 1.9 | 2.5 | 2.2 | 1.9 |
| (C) Curing agent | (C-1) Phenolic | 3.65 | 3.65 | 3.65 | 3.65 | 3.65 | 3.65 | 4.7 | 4.2 | 3.65 |
| | (C-2) Imidazole-based | 0.85 | 0.85 | 0.85 | 0.85 | 0.85 | 0.85 | 0.85 | 0.85 | 0.85 |
| | (C-3) Photo-polymerization initiator | 0.2 | 0.2 | 0.2 | 0.2 | 0.2 | 0.2 | 0.2 | 0.2 | 0.2 |
| | (C-4) Photo-polymerization initiator | | | | | | | | | |
| | (C-5) Thermal polymerization initiator | 0.5 | 0.5 | 0.5 | 0.5 | 0.5 | 0.5 | 0.5 | 0.5 | 0.5 |
| Total | | 100.0 | 100.0 | 100.0 | 100.0 | 100.0 | 100.0 | 100.0 | 100.0 | 100.0 |
| Viscosity (25° C., 50 rpm) Unit: mPa-s | | 60 | N.A | 495 | N.A | 90 | 96 | 79 | 100 | 133 |
| Aerosol Jet | ∘: Could be ejected | x | x | x | x | ∘ | ∘ | ∘ | ∘ | ∘ |
| Printing Evaluation | x: Could not be ejected | | | | | | | | | |
| Inkjet Printing | ∘: Could be ejected | ∘ | x | ∘ | x | ∘ | ∘ | ∘ | ∘ | ∘ |
| Evaluation | x: Could not be ejected | | | | | | | | | |
| Modulus of elasticity | Unit: Gpa | 5.3 | N.A | 5.7 | N.A | 2.9 | 3.4 | 2.9 | 3.8 | 4.6 |
| Tg | Unit: ° C. | 95 | N.A | 97 | N.A | 104 | 100 | 76 | 84 | 94 |
| Shrinkage rate | Unit: % | 6.6 | N.A | 6.6 | N.A | 8.3 | 7.4 | 8.5 | 6.8 | 6.6 |

| | | Ex. 6 | Ex. 7 | Ex. 8 | Ex. 9 | Ex. 10 | Ex. 11 | Ex. 12 |
|---|---|---|---|---|---|---|---|---|
| (A) Inorganic | (A-1) | | 30 | | | | | |
| particles | (A-2) | 45 | | 30 | 30 | 30 | 30 | 30 |
| (A′) Inorganic | (A′-1) | | | | | | | |
| particles | (A′-2) | | | | | | | |
| (For Comparison | (A′-3) | | | | | | | |
| Example) | (A′-4) | | | | | | | |
| (D) | (D-1) | 27.32 | 35.01 | | | | | |
| Monofunctional | (D-2) | | | 39 | 39 | | 44.55 | 39 |
| reactive diluent | | | | | | | | |
| Component (B): | (B-1) | 6.53 | 8.36 | 4.36 | 4.36 | | 23.9 | |
| Polyfunctional | (B-2) | | | | | | | 4.36 |
| (meth)acrylate | (B-3) | | | | | | | |
| compound | | | | | | | | |
| Component (B): | (B-4) | 3.60 | 4.50 | 4.50 | 4.50 | 5.00 | | 4.50 |
| Polyfunctional | (B-5) | 4.93 | 6.32 | 6.32 | 6.32 | 10.68 | | 6.32 |
| epoxy compound | (B-6) | 6.78 | 8.69 | 8.69 | 8.69 | 4.69 | | 8.69 |
| | (B-7) | 1.48 | 1.9 | 1.9 | 1.9 | 44.9 | | 1.9 |
| (C) Curing agent | (C-1) Phenolic | 2.85 | 3.65 | 3.65 | 3.65 | 3.85 | | 3.65 |
| | (C-2) Imidazole-based | 0.85 | 0.85 | 0.85 | 0.85 | 0.85 | 0.85 | 0.85 |
| | (C-3) Photo-polymerization initiator | 0.2 | 0.2 | | 0.2 | | 0.2 | 0.2 |
| | (C-4) Photo-polymerization initiator | | | 0.2 | | | | |
| | (C-5) Thermal polymerization initiator | 0.5 | 0.5 | 0.5 | 0.5 | | 0.5 | 0.5 |
| Total | | 100.0 | 100.0 | 100.0 | 100.0 | 100.0 | 100.0 | 100.0 |
| Viscosity (25° C., 50 rpm) Unit: mPa-s | | 316 | 111 | 163 | 165 | 300 | 70 | 127 |
| Aerosol Jet | ∘: Could be ejected | ∘ | ∘ | ∘ | ∘ | ∘ | ∘ | ∘ |
| Printing Evaluation | x: Could not be ejected | | | | | | | |
| Inkjet Printing | ∘: Could be ejected | ∘ | ∘ | ∘ | ∘ | ∘ | ∘ | ∘ |
| Evaluation | x: Could not be ejected | | | | | | | |
| Modulus of elasticity | Unit: Gpa | 6.3 | 5.5 | 4.4 | 4.5 | 0.5 | 6.2 | 4.5 |
| Tg | Unit: ° C. | 100 | 95 | 91.5 | 92 | 4 | 100 | 90 |
| Shrinkage rate | Unit: % | 4.4 | 6.6 | 5.5 | 5.5 | 2 | 7 | 6.3 |

All of the resin compositions in Examples 1 to 12 exhibited good ejection in both aerosol jet printing and inkjet printing.

In Comparative Example 1, which uses inorganic particles with a larger average particle size (D50) than the average particle size (D50) of (A) inorganic particles of the present invention, the viscosity was low, but the particle size of the inorganic particles was large and the resin composition could not be aerosolized and ejected in aerosol jet printing.

In Comparative Example 2, which uses inorganic particles with a smaller average particle size (D50) than the average particle size (D50) of (A) inorganic particles of the present invention, the inorganic particles could not be uniformly dispersed in the resin composition and viscosity measurements could not be taken. In addition, the resin composition of Comparative Example 2 could not be ejected by either aerosol jet printing or inkjet printing.

The resin composition of Comparative Example 3, which has a viscosity higher than that of the resin composition of the present invention, could not be ejected by aerosol jet printing.

In Comparative Example 4, the viscosity of the resin composition was too high to be measured at 25° C., 50 rpm using an E-type viscometer. In addition, the resin composition of Comparative Example 4 could not be ejected by either aerosol jet printing or inkjet printing.

The disclosure of Japanese Patent Application No. 2022-187282 (filing date: Nov. 24, 2022) is incorporated herein by reference in its entirety.

All references, patent applications, and technical standards described herein are incorporated herein by reference to the same extent as if the individual references, patent applications, and technical standards were specifically and individually noted as being incorporated by reference.

1. An insulating resin composition comprising
(A) inorganic particles with an average particle size (D50) of 0.02 to 0.5 μm,
(B) a polyfunctional thermo-curable compound, and
(C) a curing agent,
the insulating resin composition having a viscosity of 400 mPa-s or less as measured with an E-type viscometer at 25° C. and 50 rpm.

2. The insulating resin composition according to claim 1, wherein the (A) inorganic particles are surface-treated with a (meth)acrylic-based surface-treating agent.

3. The insulating resin composition according to claim 1, wherein the (B) polyfunctional thermo-curable compound contains a bifunctional thermo-curable compound.

4. The insulating resin composition according to claim 1, further comprising (D) a monofunctional reactive diluent.

5. The insulating resin composition according to claim 4, wherein a content of the (D) monofunctional reactive diluent is 40 to 80 parts by mass relative to 100 parts by mass of the total of the (B) polyfunctional thermo-curable compound, the (C) curing agent and the (D) monofunctional reactive diluent.

6. The insulating resin composition according to claim 1, wherein a content of the (A) inorganic particles is 15 to 50 parts by mass relative to 100 parts by mass of the resin composition.

7. The insulating resin composition according to claim 1, wherein the insulating resin composition is substantially free of particles with a particle size larger than 1.0 μm.

8. The insulating resin composition according to claim 1, wherein the insulating resin composition is usable in aerosol jet printing.

9. The insulating resin composition according to claim 1, wherein the insulating resin composition is usable in inkjet printing.

10. A cured product in which the insulating resin composition according to to claim 1 has been cured.

11. An electronic component comprising the cured product according to claim 10.

12. An aerosol jet printing method comprising aerosol jet printing the insulating resin composition according to claim 1 onto an object.

13. An inkjet printing method comprising inkjet printing the insulating resin composition according to claim 1 onto an object.

14-15. (canceled)

16. The aerosol jet printing method according to claim 12, wherein the (A) inorganic particles are surface-treated with a (meth)acrylic-based surface-treating agent.

17. The aerosol jet printing method according to claim 12, wherein the (B) polyfunctional thermo-curable compound contains a bifunctional thermo-curable compound.

18. The aerosol jet printing method according to claim 12, wherein the insulating resin composition further comprises (D) a monofunctional reactive diluent.

19. The aerosol jet printing method according to claim 18, wherein a content of the (D) monofunctional reactive diluent is 40 to 80 parts by mass relative to 100 parts by mass of the total of the (B) polyfunctional thermo-curable compound, the (C) curing agent and the (D) monofunctional reactive diluent.

20. The aerosol jet printing method according to claim 12, wherein a content of the (A) inorganic particles is 15 to 50 parts by mass relative to 100 parts by mass of the resin composition.

21. The aerosol jet printing method according to claim 12, wherein the insulating resin composition is substantially free of particles with a particle size larger than 1.0 μm.
